(19) United States
(12) Patent Application Publication
(10) Pub. No.: US 2019/0242403 A1
(43) Pub. Date: Aug. 8, 2019

(54) HEAT DISSIPATING FAN AND ELECTRONIC DEVICE HAVING THE SAME

(71) Applicant: CHAMP TECH OPTICAL (FOSHAN) CORPORATION, Foshan (CN)

(72) Inventors: XIAO-GUANG MA, Foshan (CN); YUNG-PING LIN, New Taipei (TW); ZHENG LUO, Foshan (CN)

(21) Appl. No.: 15/972,210

(22) Filed: May 6, 2018

(30) Foreign Application Priority Data
Feb. 6, 2018 (CN) 201810115913.6

(51) Int. Cl. F04D 29/42; H05K 7/20; F04D 29/66

(52) U.S. Cl. CPC F04D 29/4226; G06F 1/203; F04D 29/668; H05K 7/20172

(57) ABSTRACT

A heat dissipating fan includes a housing, a stator, and a rotor. The housing includes a base. A hollow tube protrudes from a surface of the base. A through-hole is defined on the hollow tube. The housing further includes a barrel, a first buffered structure formed on a whole outer surface of the barrel, and a second buffered structure. An end portion of the barrel is received in the through-hole. The barrel and the hollow tube are separated by the first buffered structure. The stator is sleeved on the first buffered structure. The second buffered structure is annular and formed on an outer surface of the first buffered structure to resist between the hollow tube and the stator, thereby separating the hollow tube and the stator. The rotor is mounted on the barrel by a shaft. The disclosure also provides an electronic device having the heat dissipating fan.

### FIELD

The subject matter herein generally relates to a heat dissipating fan and an electronic device having the heat dissipating fan.

### BACKGROUND

A traditional fan includes a stator, a rotor, and a fan frame receiving the stator and the rotor. In operation, the rotor is driven by a motor to rotate relative to the stator, therefore dissipating heat generated from electronic elements. However, because of uneven mass distribution of the rotor and transformed moments of the motor, vibration and noise can be caused when the fan is working and stability of an electronic device including the fan is reduced.

### BRIEF DESCRIPTION OF THE DRAWINGS

Implementations of the present technology will now be described, by way of example only, with reference to the attached figures.

FIG. 1 is a diagram of an embodiment of a heat dissipating fan.

FIG. 2 is a cross-sectional view taken along line II-II of FIG. 1.

FIG. 3 is diagram of an embodiment of an electronic device having the heat dissipating fan of FIG. 1.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale, and the proportions of certain parts may be exaggerated to better illustrate details and features of the present disclosure.

The disclosure is illustrated by way of example and not by way of limitation in the figures of the accompanying drawings, in which like references indicate similar elements. It should be noted that references to “an” or “one” embodiment in this disclosure are not necessarily to the same embodiment, and such references mean “at least one.”

The term “comprising,” when utilized, means “including, but not necessarily limited to”; it specifically indicates open-ended inclusion or membership in the so-described combination, group, series, and the like.

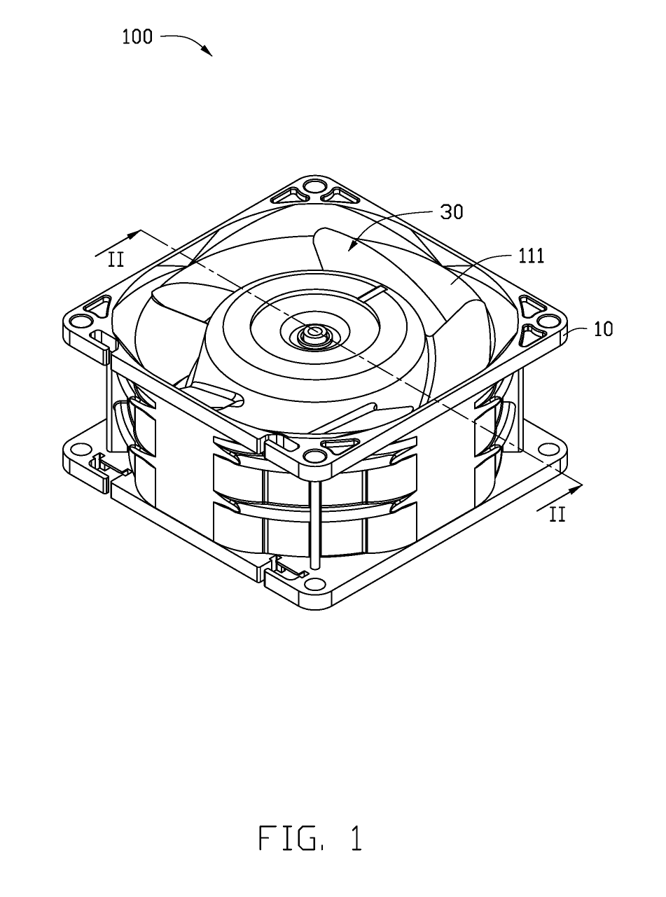

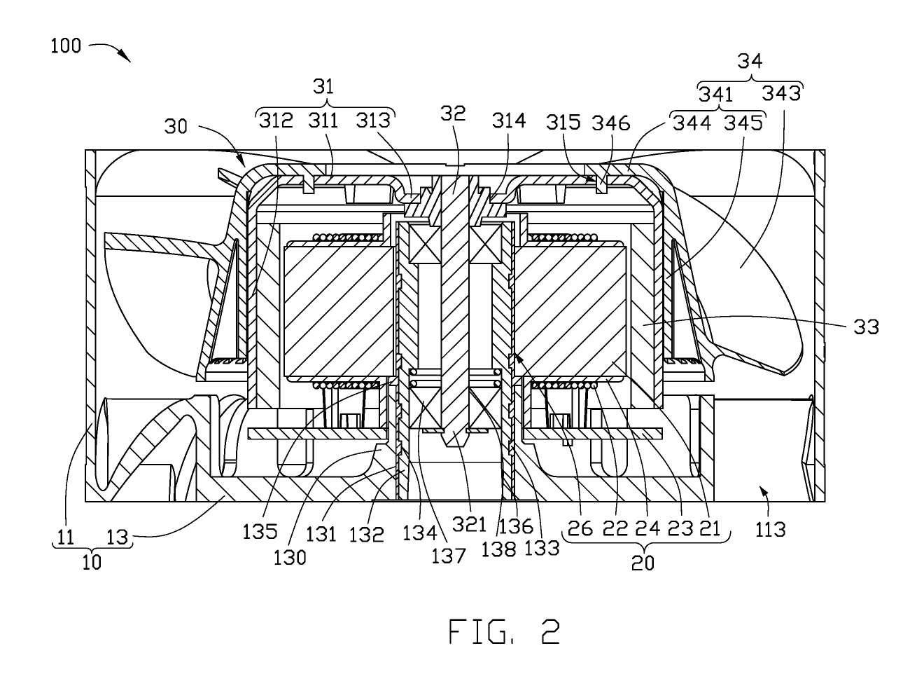

FIGS. 1 and 2 illustrate an embodiment of a heat dissipating fan 100. The heat dissipating fan 100 comprises a housing 10, a stator 20 received in the housing 10, and a rotor 30 received in the housing 10.

The housing 10 comprises a hollow casing 11 and a base 13. The hollow casing 11 defines an air inlet 111 at a top side thereof and an air outlet 113 facing away from the air inlet 111 at a bottom side thereof. The air outlet 113 surrounds base 13.

A hollow tube 130 protrudes from a central portion of an upper surface of the base 13 and towards the air inlet 111. A through-hole 131 is defined in the hollow tube 130 along a protruding direction of the hollow tube 130.

The housing 10 further comprises a barrel 132. An end portion of the barrel 132 is received and fixed in the hollow tube 130. A first buffered structure 133 is formed on a whole outer surface of the barrel 132 by a spraying technique or an injection-molding technique, to cause the barrel 132 and the hollow tube 130 to be separated by the first buffered structure 133.

The housing 10 further comprises a second buffered structure 135. The second buffered structure 135 is annular and formed on an outer surface of the first buffered structure 133. The second buffered structure 135 resists against an end of the hollow tube 130.

In at least one embodiment, the first buffered structure 133 and the second buffered structure 135 are integrally formed with each other. In another embodiment, the second buffered structure 135 is removably sleeved on the outer surface of the first buffered structure 133.

The first buffered structure 133 and the second buffered structure 135 are made of damping material. The damping material may be silicon resin, rubber, plastic, or sponge.

In at least one embodiment, at least one groove 134 is defined in the outer surface of the barrel 132. The first buffered structure 133 covers the whole outer surface of the barrel 132 and fully infills the groove 134.

The barrel 132 comprises a receiving hole 136 defined along an axial direction of the barrel 132. Two bearings 137 are received and fixed in the receiving hole 136. Each bearing 137 comprises an axle hole 138 along the axial direction of the barrel 132.

In at least one embodiment, the base 13 is formed on the outer surface of the first buffered structure 133 by an injection-molding technique. The base 13 and the hollow casing 11 may be integrally formed with each other. In another embodiment, the base 13 and the hollow casing 11 may be separable and fixed with each other by a connector, such as a screw.

The stator 20 comprises a stator core 21, a plurality of stator coils 22, a printed circuit board (PCB) 23, and an electrically insulating frame 24. The electrically insulating frame 24 encloses the stator core 21. The stator coils 22 are wound on the electrically insulating frame 24 and around the stator core 21. Thus, the stator coils 22 are electrically separated from the stator core 21 by the electrically insulating frame 24. The PCB 23 is attached to a bottom side of the electrically insulating frame 24, and is electrically connected with the stator coils 22 to control an electrical current flowing through the stator coils 22. A through hole is defined in each of the stator core 21, the electrically insulating frame 24, and the PCB 23. The through holes of the stator core 21, the electrically insulating frame 24, and the PCB 23 are coaxial, and cooperatively define a mounting hole 26. The mounting hole 26 is centered along an axial direction of the stator 20.

The mounting hole 26 of the stator 20 is sleeved on the first buffered structure 133, and the stator 20 resists against a side of the second buffered structure 135 facing away from the base 13. The first buffered structure 133 and the second buffered structure 135 are located in a transmitting path of vibrations between the stator 20 and the base 13, so the first buffered structure 133 and the second buffered structure 135 absorb the vibrations. Noise from the heat dissipating fan 100 and the impact of vibrations on the housing 10 and other elements are thus reduced. Since the housing 10 is used for connecting other cooling elements and is isolated from the vibrations during operation, the connection between the housing 10 and the cooling elements is protected.

The rotor 30 comprises a cylindrical hub 31, a shaft 32, a magnet 33, and a fan blade 34. The cylindrical hub 31 comprises a first top wall 311 and a first sidewall 312 extending downwardly from a circumferential edge of the first top wall 311. A shaft seat 313 is formed in a central portion of the first top wall 311. An installing hole 314 is defined on the shaft seat 313. In at least one embodiment, at least one connecting hole 315 is defined on the first top wall 311 around the shaft seat 313.

One end portion of the shaft 32 is mounted in the installing hole 314, and another end portion of the shaft 32 extends downwardly from the shaft seat 313 to form a bottom free end 321.

The magnet 33 is arranged on an inner surface of the first sidewall 312. In at least one embodiment, the magnet 33 is annular.

In at least one embodiment, the fan blade 34 covers the cylindrical hub 31 and is fixed on the cylindrical hub 31. The fan blade 34 comprises a blade support 341 and a plurality of blades 343. The blade support 341 comprises a second top wall 344 corresponding to the first top wall 311 and a second sidewall 345 extending downwardly from a circumferential edge of second top wall 344. At least one holding part 346 is formed on an inner surface of the second top wall 344. The holding part 346 is engaged with the connecting hole 315 to fix the fan blade 34 on the cylindrical hub 31. The blades 343 extend obliquely outwardly from an outer periphery of the second sidewall 345 of the blade support 341. The blades 343 are spaced from each other.

The bottom free end 321 of the shaft 32 is mounted on the bearings 137 through the axle hole 138. The first buffered structure 133 is located in a transmitting path of vibrations between the rotor 30, the stator 20 and the base 13, so the first buffered structure 133 absorbs the vibrations, thereby reducing an impact of the vibrations on the housing 10 and reducing a noise of the heat dissipating fan 100.

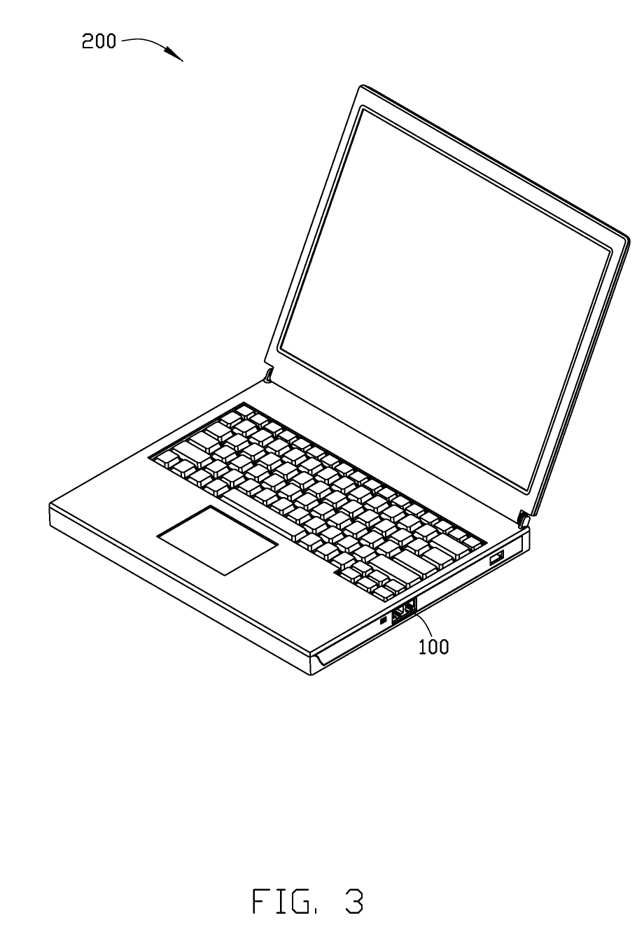

Referring to FIG. 3, the heat dissipating fan 100 can be used in an electronic device 200 having at least one heat-generating component. The electrical device 200 can be a computer, a laptop, or a server. The heat-generating component can be a CPU. The heat dissipating fan 100 can be used for dispersing heat energy generated by the heat-generating component.

It is to be understood, even though information and advantages of the present embodiments have been set forth in the foregoing description, together with details of the structures and functions of the present embodiments, the disclosure is illustrative only; changes may be made in detail, especially in matters of shape, size, and arrangement of parts within the principles of the present embodiments to the full extent indicated by the plain meaning of the terms in which the appended claims are expressed.

What is claimed is:

1. A heat dissipating fan comprising:
a housing comprising:
a base;
a hollow tube protruding from a surface of the base, a through-hole defined on the hollow tube along a protruding direction of the hollow tube;
a barrel;
a first buffered structure formed on a whole outer surface of the barrel; and
a second buffered structure;
a stator received in the housing; and
a rotor received in the housing;
wherein an end portion of the barrel is received in the through-hole, the barrel and the hollow tube is separated by the first buffered structure, the stator is sleeved on the first buffered structure, the second buffered structure is annular and formed on an outer surface of the first buffered structure, the second buffered structure resists between an end of the hollow tube and the stator to separate the hollow tube and the stator, the rotor is mounted on the barrel by a shaft.

2. The heat dissipating fan of claim 1, wherein the first buffered structure is formed on the whole outer surface of the barrel by a spraying technique or an injection-molding technique.

3. The heat dissipating fan of claim 2, wherein the first buffered structure and the second buffered structure are integrally formed with each other.

4. The heat dissipating fan of claim 2, wherein the second buffered structure is movably sleeved on the outer surface of the first buffered structure.

5. The heat dissipating fan of claim 1, wherein the barrel comprises a receiving hole defined along an axial direction of the barrel, two bearings are received in the receiving hole, and the shaft is mounted on the bearings.

6. The heat dissipating fan of claim 1, wherein the base is formed on the outer surface of the first buffered structure by an injection-molding technique.

7. The heat dissipating fan of claim 1, wherein the first buffered structure and the second buffered structure are made of damping material selected from silicon resin, rubber, plastic, and sponge.

8. The heat dissipating fan of claim 1, wherein at least one groove is defined on the outer surface of the barrel, the first buffered structure covers the whole outer surface of the barrel and fully infills the groove.

9. An electronic device comprising at least one heat dissipating fan, each heat dissipating fan comprising:
a housing comprising:
a base;
a hollow tube protruding from a surface of the base, a through-hole defined on the hollow tube along a protruding direction of the hollow tube;
a barrel;
a first buffered structure formed on a whole outer surface of the barrel; and
a second buffered structure;
a stator received in the housing; and
a rotor received in the housing;
wherein an end portion of the barrel is received in the through-hole, the barrel and the hollow tube is separated by the first buffered structure, the stator is sleeved on the first buffered structure, the second buffered structure is annular and formed on an outer surface of the first buffered structure, the second buffered structure resists between an end of the hollow tube and the stator to separate the hollow tube and the stator, the rotor is mounted on the barrel by a shaft.

10. The electronic device of claim 9, wherein the first buffered structure is formed on the whole outer surface of the barrel by a spraying technique or an injection-molding technique.

11. The electronic device of claim 10, wherein the first buffered structure and the second buffered structure are integrally formed with each other.

12. The electronic device of claim 10, wherein the second buffered structure is movably sleeved on the outer surface of the first buffered structure.

13. The electronic device of claim 9, wherein the barrel comprises a receiving hole defined along an axial direction of the barrel, two bearings are received in the receiving hole, and the shaft is mounted on the bearings.

14. The electronic device of claim 9, wherein the base is formed on the outer surface of the first buffered structure by an injection-molding technique.

15. The electronic device of claim 9, wherein the first buffered structure and the second buffered structure are made of damping material selected from silicon resin, rubber, plastic, and sponge.

16. The electronic device of claim 9, wherein at least one groove is defined on the outer surface of the barrel, the first buffered structure covers the whole outer surface of the barrel and fully infills the groove.
